(19) United States
(12) Patent Application Publication
(10) Pub. No.: US 2015/0155413 A1
(43) Pub. Date: Jun. 4, 2015

(54) SOLAR THERMOELECTRIC GENERATOR WITH INTEGRATED SELECTIVE WAVELENGTH ABSORBER

(71) Applicants: Uttam GHOSHAL, Austin, TX (US); Ayan GUHA, Austin, TX (US); Himanshu POKHARNA, (US); SHEETAK, INC., Austin, TX (US)

(72) Inventors: Uttam Ghoshal, Austin, TX (US); Ayan Guha, Austin, TX (US); Himanshu Pokharna, Saratoga, CA (US)

(73) Assignee: SHEETAK, INC., Austin, TX (US)

(21) Appl. No.: 14/401,457

(22) PCT Filed: May 15, 2013
(86) PCT No.: PCT/US13/41132

§ 371 Date: Nov. 14, 2014

Related U.S. Application Data
(60) Provisional application No. 61/647,435, filed on May 15, 2012.

(51) Int. Cl. H01L 31/052; H02S 40/44; H01L 35/30; H01L 31/18; H01L 35/34

(52) U.S. Cl. CPC H01L 31/0525; H01L 31/18; H01L 35/34; H01L 35/30; H02S 40/44

(57) ABSTRACT

The present disclosure is related to an apparatus for generating electric power from selected wavelengths of electromagnetic radiation and a method of manufacture of said apparatus. The apparatus may include a selective wavelength absorber that is thermally coupled to a thermoelectric generator. The selective wavelength absorber may include alternating absorber and dielectric layers configured to absorb and reflect selected wavelengths of electromagnetic radiation. Absorbed electromagnetic radiation may be converted to heat energy for driving the thermoelectric generator. The method may include manufacturing the selective wavelength absorber, including depositing the alternating layers on a substrate that has been formed to receive the electromagnetic radiation at a selected angle or range of angles.

### CROSS REFERENCE TO RELATED APPLICATIONS

This application claims the benefit of Provisional U.S. Patent Application No. 61/647,435 filed May 15, 2012) which application is hereby incorporated by reference in its entirety,

### BACKGROUND OF THE DISCLOSURE

I. Field of the Disclosure

The present disclosure relates to an apparatus and method for generating electric power, and, in particular, generating electric power from electromagnetic radiation energy using a thermoelectric generator.

2. Description of the Related Art

Many solid state electrical devices, such as photovoltaic cells or photoelectric cells or solar cells, are already used for generating electrical energy from incident solar radiation in the visible or near visible spectrum. Although photovoltaic cells are popular solution for converting solar energy to electrical energy, they are also expensive (on a cost per watt generated basis). The expensive nature of photovoltaic cells ma be traced back to complex fabrication processes, high cost of production, space constraints, efficiency, material costs, etc. Furthermore, common photovoltaic cells absorb a narrow band of optical electromagnetic radiation instead of the entire solar electromagnetic spectrum that reaches the surface of the Earth. Advanced photovoltaic cells, such as triple junction solar cells, have even more complicated fabrication processes and resulting higher costs. What is needed is an apparatus designed to capture a broader range of frequencies without adding more complexity to the fabrication process of the light to electrical energy converting apparatus.

### BRIEF SUMMARY OF THE DISCLOSURE

In aspects, the present disclosure is related to at apparatus and method for generating electric power, and, in particular, generating electric power from electromagnetic radiation using a thermoelectric generator. In some aspects, the present disclosure is related to generating electric power using a selected wavelength absorber with the thermoelectric generator.

One embodiment according to the present disclosure includes an apparatus for generating electric power from electromagnetic radiation, the apparatus comprising: a thermoelectric gene r, the thermoelectric generator having a hot side and a cold side; and an electromagnetic radiation absorber in thermal communication with the hot side of the thermoelectric generator and configured to convert electromagnetic energy into beat energy,

The electromagnetic radiation absorber may have high absorbance and low emittance over an operating temperature range of the thermoelectric generator. The electromagnetic radiation absorber may be configured to absorb electromagnetic radiation in the visible spectrum. The electromagnetic radiation absorber may be configured to have low emittance of electromagnetic radiation in the infra-red spectrum. The electromagnetic radiation absorber may comprise: a plurality of absorber layers; and a plurality of dielectric layers, wherein the absorber layers and the dielectric layers alternate in placement. The absorber layers may comprise a titanium dioxide layer and a magnesium oxide layer. The dielectric layers may comprise molybdenum. The absorber and dielectric layers may be formed into a pyramidal shape, and the pyramidal shape may be dimensioned based on a selected range of electromagnetic radiation that is to be absorbed.

The apparatus may also include a housing, wherein the thermoelectric generator and the electromagnetic radiation absorber are disposed in the housing, and wherein the housing is transparent to a selected range of electromagnetic radiation on a side of the housing that is between an electromagnetic radiation source and the electromagnetic radiation absorber. The housing may be configured maintain to a vacuum or be filled with aerogel.

The thermoelectric generator comprises at least one thermocouple. The at least one thermocouple may include at least one n-type thermoelement in thermal communication with the electromagnetic radiation absorber; a first substrate layer in thermal communication with the at least one n-type thermoelement; at least one p-type thermoelement in thermal communication with the electromagnetic radiation absorber; a second substrate layer in thermal communication with the at least one p-type thermoelement, and a foil layer in thermal communication with the first substrate layer and the second substrate layer. An optional first radiation shield may be disposed between the electromagnetic radiation absorber and the thermoelement. Each thermoelement may have an optional metal substrate layer disposed between the thermoelement and the electromagnetic radiation absorber. The thermocouple may also include an n-side second radiation shield disposed between the at least one n-type thermoelement and the first substrate layer; and a p-side second radiation shield disposed between the at least one p-type thermoelement and the second substrate layer. The foil layer may be an anodized metal. The foil layer may have a thermal expansion coefficient substantially similar to the thermal expansion coefficient of the housing. The foil layer may be configured to give structural support to the thermocouple,

Each of the thermoelements may include a constricted contact; a diffusion barrier disposed on the constricted contact, a lower electrical contact disposed on the first diffusion barrier; a plurality of thin-film thermoelectric layers (n-type or p-type depending on the thermoelement) in thermal communication with the first metal substrate; and an upper electrical contact disposed between the plurality of n-type thin-film thermoelectric layers and the first metal substrate. The electrical contacts may be high power factor electrodes. The n-type layers may include one or more of: Bi₂Te_{2S}Se_{0.2}. PbTe, AgP₁₈SbTe₂₀, PbTe/SrTe—Na, Ba_{0.08}Yb_{0.09}Co₄Sb₁₂, Mg₂Si_{0.4}Sn_{0.6}, TiNiSn, SrTiO₃, P-doped Si_{0.8}Ge_{0.2}, and La₃Te₄. The p-type layers may include one or more of: Bi_{0.5}Sb_{1.5}Te₃, Zn₄Sb₃, CeFe_{3.5}Co_{0.5}Sb₁₂, Yb₁₄MnSb₁₁, MnSi_{1.73}, NaCo2O4, B-doped Si, and B-doped Si_{0.8}Ge_{0.2}.

Another embodiment according to the present disclosure includes a method of convening electromagnetic radiation to heat energy, the method comprising the steps of: receiving the electromagnetic radiation with an apparatus, the apparatus comprising: a thermoelectric generator, the thermoelectric generator having a hot side and a cold side; and an electromagnetic radiation absorber in thermal communication with the hot side and configured to convert electromagnetic energy into heat energy. The method may also include one or more steps of: it concentrating the electromagnetic radiation on the electromagnetic radiation absorber and ii) redirecting the electromagnetic radiation from an electromagnetic source on to the electromagnetic radiation absorber.

Another embodiment according to the present disclosure includes a method of manufacturing an electromagnetic radiation driven thermoelectric generator, the method comprising the steps of: forming an electromagnetic radiation absorber; and disposing the electromagnetic radiation absorber in thermal communication with a hot side of a thermoelectric generator. The forming step may include: depositing a silicon dioxide layer on a silicon substrate; removing a part of the silicon dioxide layer to expose the silicon substrate; forming trenches in the silicon substrate; removing a remainder of the silicon dioxide layer from the silicon substrate; depositing a barrier layer on the silicon substrate; depositing alternating layers of electromagnetic absorber material and dielectric material on the barrier layer; depositing a nickel layer on the alternating layers; thinning the silicon substrate; and removing the barrier layer from the alternating layers.

Examples of the more important features of the disclosure have been summarized rather broadly in order that the detailed description thereof that follows may be better understood and in order that the contributions they represent to the art may be appreciated. There are, of course, additional features of the disclosure that will be described hereinafter and which will form the subject of the claims appended hereto.

### BRIEF DESCRIPTION OF THE DRAWINGS

For a detailed understanding of the present disclosure, reference should be made to the following detailed description of the embodiments, taken in conjunction with the accompanying drawings, in which like elements have been given like numerals, wherein:

FIG. 1 a schematic of a solar thermoelectric apparatus according to one embodiment of the present disclosure;

FIG. 2 is a schematic of a thermoelement for use in the solar thermoelectric apparatus of FIG. 1 according to one embodiment of the present disclosure;

FIG. 3 is a schematic of another solar thermoelectric apparatus according to one embodiment of the present disclosure;

FIG. 4 is a schematic solar panel made up of solar thermoelectric apparatuses according to one embodiment of the present disclosure;

FIG. 5A is a schematic of a solar tube panel according to one embodiment of the present disclosure;

FIG. 5B is a schematic cross-section of a solar tube suitable for use in the solar tube panel of FIG. 5A according to one embodiment of the present disclosure;

FIG. 6 is a schematic of a section of the selective wavelength absorber according to one embodiment of the present disclosure;

FIG. 7 is a graph of absorption versus wavelength for a selective wavelength absorber according to one embodiment of the present disclosure;

FIG. 8 is a flow chart of a method of manufacturing a selected wavelength absorber according to one embodiment of the present disclosure:.

FIG. 9A is a cross-section of a substrate for conversion into a selective wavelength absorber according to one embodiment of the present disclosure;

FIG. 9B is a cross-section of the substrate of FIG. 9A after patterning according to one embodiment of the present disclosure;

FIG. 9C is a cross-section of a substrate of FIG. 9B after anisotropic etching according to one embodiment of the present disclosure;

FIG. 9D is a cross-section of a substrate of FIG. 9C after addition of a barrier layer according to one embodiment of the present disclosure:.

FIG. 9E is a cross-section of a substrate of FIG. 9D with a stack of alternating layers according to one embodiment of the present disclosure;

FIG. 9F is a cross-section of a substrate of FIG. 9E after nickel electroplating according to one embodiment of the present disclosure;

FIG. 9G is a cross-section of a substrate of FIG. 9F after dry etching, and release of foil according to one embodiment of the present disclosure; and

FIG. 9H is a cross-section of a substrate of FIG. 9G after wet etching of the barrier layer according to one embodiment of the present disclosure.

### DETAILED DESCRIPTION OF THE DISCLOSURE

Generally, the present disclosure relates to an apparatus and method for generating electric power, and, in particular, generating electric power from electromagnetic radiation using a thermoelectric generator with a selective wavelength absorber. In some aspects, the present disclosure is related to generating, electric power using incident solar radiation. The, present disclosure is susceptible to embodiments of different forms. They are shown in the drawings, and herein will be described m detail, specific embodiments of the present disclosure with the understanding, that the present disclosure is to be considered an exemplification of the principles of the present disclosure and is not intended to limit the present disclosure to that illustrated and described herein.

The thermoelectric generators (TEG) may be a cost effective solution (e.g., low cost incurred per watt of power generation) for converting incident solar radiation energy to electric energy because of simpler device structures when compared to photovoltaic cells. Some TEGs may be fabricated by thin film wafer-based manufacturing techniques to reduce cost. TEGs may be combined with efficient electromagnetic radiation absorbers that collect energy from the solar spectrum, including sections of the spectrum that are typically not captured by photovoltaic solar cells.

Generally, the conversion of incident solar radiation into electrical energy is a two step process. First, the solar radiation or light is convened to heat. Second, the heat energy is converted to electrical energy by the TEG.

To enhance the performance of the capture of incident solar radiation on the hot side of the TEG, the incident solar radiation may be focused or captured through the use of radiation absorbers, optical concentrators, and thermal concentrators. The efficient capture and conversion of solar radiation to heat on the hot side of the TEG may increase the efficiency of the overall system.

Generally, the power output of the TEG is related to the design of the TEG and the temperature differential between the hot and cold sides of the. TEG. The heat to electrical energy efficiency of a TEG is generally calculated by:

$${η}_{tc} = ( \frac{{T}_{h} - {T}_{c}}{{T}_{h}} ) [ \frac{\sqrt{1 + {ZT}_{m}} - 1}{\sqrt{1 + {ZT}_{m}} + {T}_{c} / {T}_{h}} ] \qquad ( 1 )$$

where ηₕ denotes the efficiency of the solar TEG, Tₕ is temperature of a hot side of the solar TEG, T_{c} is the temperature of a cold side of the solar TEG, Tₘ is the average temperature across the solar TEG, and ZTₘ is the figure of merit of the thermoelectric materials in the thermoelements. From equation (1), it may be observed that the efficiency of the solar thermoelectric generators depends On temperature differential and the figure of merit in some embodiments, the TEG may be configured to operate effectively with a temperature differential of 300 degrees Celsius or more. Additionally., a solar thermoelectric generator may also use thermoelectric devices with high figure of merit, i.e. ZTₘ>1.

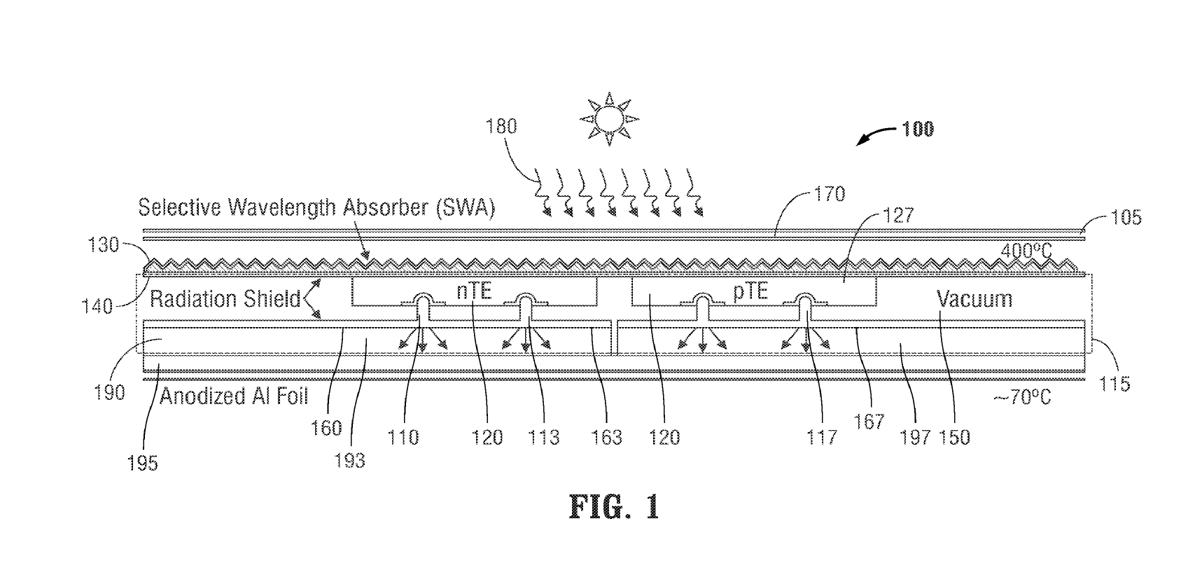

FIG. 1 shows a diagram of an exemplary solar TEG apparatus 100 according to one embodiment of the present disclosure. The solar TEG apparatus 100 may include an evacuated housing 105, such as a tube or panel. The evacuated housing 105 may surround a plurality of elements. The plurality of elements may include a thermocouple 115 and a selective wavelength absorber 130. The thermocouple 115 may include two or more thermoelements 110. The two or more thermoelements 110 includes at least one n-type thermoelement 113 and at least one p-type thermoelement 117. Each of the thermoelements 110 may be disposed on metal substrates 120. The n-type thermoelements 113 may be disposed on a first metal substrate 123, and the p-type thermoelements may be disposed on a second metal substrate 127. The metal substrates 120 may be in thermal communication with the selective wavelength absorber 130.

The selective wavelength absorber 130 may be configured to absorb electromagnetic radiation hum the Sun or other electromagnetic sources that have color temperatures in the visible light spectrum (typically the Sun has a color temperature around 6000K). The selective wavelength absorber 130 may also be configured to have a low emittance of light in the infrared spectrum, such as in the color temperature range of 500-800K. Thus, the incoming photons are converted to heat that is transmitted to the thermocouple 115, ii) reflected to another part of the selective wavelength absorber 130 or into free space, or iii) reemitted as less energetic, photons (infrared).

The metal substrates 120 (when present) may be configured to conduct heat from the selective wavelength absorber 130 to the thermoelements 110. The metal substrates 120 are both electrically and thermally conductive, however, the metal substrates 120 are not limited so solely metal materials. In some embodiments, the metal substrates 120 may include, but are not limited to, composite structures with metal layers such as copper or tungsten bonded over ceramics. In some embodiments, the metal substrates 120 may be configured as thermal contractors to focus the heat energy on the thermoelements 110.

A primary radiation shield 140 may be disposed between the selective wavelength absorber 130 and the metal substrates 120. The primary radiation shield 140 may be configured to reduce radiation loss from the backside of the selective wavelength absorber 130. In some embodiments, inclusion of the one or both of the primary radiation shield 140 and the metal substrates 120 may be optional, so long as the thermoelements 110 remain in thermal communication with the selective wavelength absorber 130.

The thermoelements 110 and the metal substrates 120 may be surrounded by a vacuum 150. The housing 105 may be configured to maintain the vacuum 150. Part of the evacuated housing 105 may be an optional lens 170 which may be disposed between incoming electromagnetic radiation 180 and the selective wavelength absorber 130. The lens 170 may be transparent to the incoming electromagnetic radiation 180 on the selective wavelength absorber 130. In some embodiments, the lens 170 may also be configured to concentrate the incoming electromagnetic radiation 180 on the selective wavelength absorber 130. In some embodiments, the lens 170 may include one or more of i) a parabolic trough, ii) mirrors, and iii) a Fresnel lens. In some embodiments, the concentration of the incoming electromagnetic radiation 180 may be achieved using compound parabolic-concentrators (not shown).

The thermoelements 110 may be disposed on a set of secondary radiation shields 160. The secondary radiation shields 160 may include a secondary radiation shield 163 associated with the n-type thermoelements 113 and a secondary radiation shield 167 associated with the p-type thermoelements 117. In some embodiments, inclusion of one or both of the radiation shields 140, 160 may be optional In some embodiments, the radiation shields 140, 160 may be used. Then the operating temperature of the selective wavelength absorber 130 is about 200 degrees Celsius and higher. The radiation shields 140 160 may be configured to prevent radiative heat transfer losses. In some embodiments, the radiation shields 140, 160 may be made of gold and/or platinum. The use of gold and/or platinum as the radiation shields 140,160 is exemplary and illustrative only,as other thermally conductive, low emissivity materials may be used as would be understood by a person of ordinary skill in the art with the benefit of the present disclosure. In some embodiments, the primary radiation shield. 140 may be suitably conductive so as to render inclusion of the metal substrates 120 optional. The radiation shields 140, 160 may have low emissivity. In some embodiments, both sides of the radiation shields 140, 160 may be polished to further lower its emissivity.

The substrate layers 190 may includes a substrate layer 193 in thermal communication with one or more n-type thermoelements 113 and a substrate layer 197 in thermal communication with one or more p-type thermoelements 117. The substrate layers 190 may be electrically and thermally conductive. In some embodiments, the substrate layers 190 may be of the same material as metal substrate layers 120. Each of the secondary radiation shields 163, 167 may be configured to allow their respective thermoelements 113, 117 to he in thermal contact with their respective substrate layers 193, 197. The secondary radiation shields 163, 167 may be disposed between their respective thermoelements 113, 117 and their respective substrate layer 193, 197. The substrate layers 190 may be disposed on a foil layer 195. The foil layer 195 may be made of a material that is thermally conductive and electrically insulating. The foil layer 195 may be made of or include an anodized aluminum foil. The use of anodized aluminum for the foil layer 195 is exemplary and illustrative only, as other suitable materials, such as anodized nickel and anodized tungsten, may be used as well. In some embodiments, the foil layer 195 may be configure(to have a thermal expansion coefficient that is substantially identical to the e thermal expansion coefficient of the housing 105.

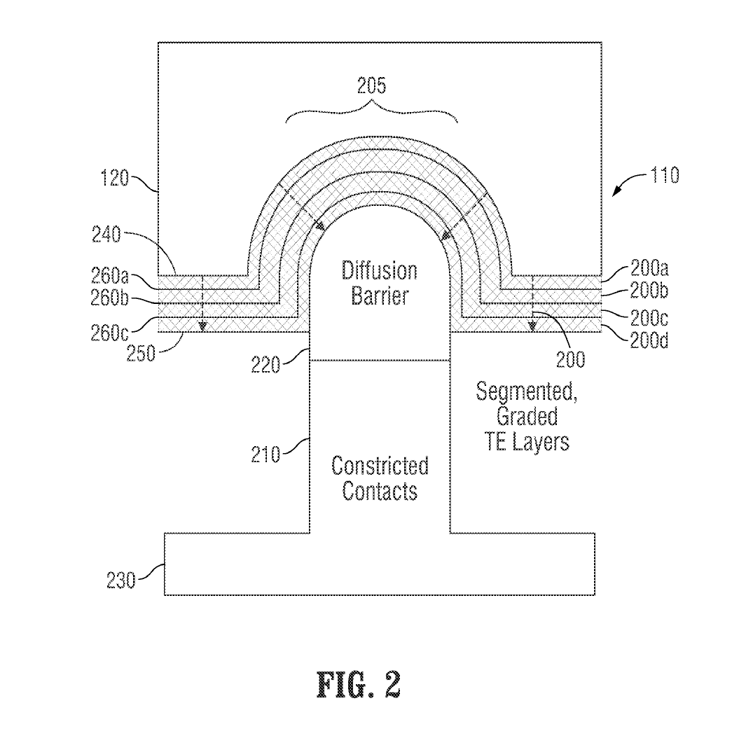

FIG. 2 shows a diagram of an exemplary thermoelement 110 in contact with one of the metal substrates 120. The n-type thermoelements 113 and the Hype thermoelements 117 may have identical structures but there compositions may differ. The thermoelement 119 may include, a plurality of thermoelectric layers 200, a constricted contact 210, and a diffusion barrier 220. The plurality of thermoelectric layers 200 may include one or more layers 200a, 200b, 200c, 200d that are configured to operate at different temperatures and/or different temperature differentials between the hot and cold sides of each layer 100a, 200b. 200c, 200d. An exemplary set of thermoelectric layers and operating temperature ranges are shown in Table 1.

TABLE 1

| | | Operating |
|---|---|---|
| P-type TE Material | N-type TE Material | Temperature (° C.) |
| Bi_{0.5}Sb_{1.5}Te₃ | Bi₂Te_{2.8}Se_{0.2} | −50 to 250 |
| Zn₄Sb₃ | PbTe | 250-450 |
| | AgPb₁₈SbTe₂₀ | |
| | PbTe/SrTe-Na | |
| CeFe_{3·5}Co_{0·5}Sb₁₂ | Ba_{0.08}Yb_{0.09}Co₄Sb₁₂ | 400-650 |
| Yb₁₄MnSb₁₁ | Mg₂Si_{0.4}Sn_{0.6} | 500-700 |
| MnSi_{1.73} | TiNiSn | |
| NaCo₂O₄ | SrTiO₃ | |
| B-doped Si | P-doped Si | 600-1000 |
| B-doped Si_{0·8}Ge_{0.2} | P-doped Si_{0·8}Ge_{0.2} | |
| | La₃Te₄ | |

Each thermoelectric layer 100a, 200b, 200c, 200d may be separated from the other by a phonon blocking layer 160a, 260b, 260c. The phonon blocking layers 269a, 260b, 260c (collectively 260) are configured to reduce heat conduction between the thermoelectric layers 200a, 200b, 200c, 200d via phonon transport. The phonon blocking layers 260a, 260b, 260c may include thin layers of metals or oxides disposed between the thermoelectric layers 200. The phonon blocking layers 260 may reduce the heat conduction is phonon transport m the thermoelement layers 200 without increasing the electrical resistance of the thermoelement layers 200. The electronic transport across the phonon blocking layers 260 may occur by tunneling. Since the speed of propagation of an acoustic phonon is much lower in liquids than in solids, low melting point metals (e.g. tin, indium) are suitable phonon blocking layers. In some embodiments, the phonon blocking may be enhanced when the thermoelement 110 is operating at temperatures close to the melting temperature of the phonon blocking layer material. The phonon blocking layers 260 may be made of, but are not limited to, one or more of: 1) titanium,) ii) titanium tungsten, iii) gallium, iv) indium, v) tin, and s aluminum oxide.

The constricted contacts 210 are electrically and thermally conducting structures of geometric dimensions much smaller than the thickness of the metal substrate 120. The constricted contacts 210 are typically cylindrical in shape with diameters of about 50 microns or less. The constricted contacts 210 may be configured to control the electrical and thermal resistance of the thermoelement 110.

The diffusion barriers 220 may be configured to reduce or eliminate the diffusion of metals constituting the constricted contact 210 into the thermoelectric layers 200. Exemplary diffusion barrier materials may include, but are not limited to one or more of i) tantalum, ii) tantalum nitride, iii) titanium, iv) titanium nitride, v) titanium tungsten, and vi) zirconium.

A first electrode 240 may be disposed between the metal substrate 120 and the thermoelectric layers 200. A second electrode 250 may be disposed between the thermoelectric layers 200 and the diffusion barrier 220. The electrodes 240, 250 may be made of as high power factor material. The power factor is expressed as S²σ, where S is the Seebeck coefficient and σ is the electrical conductivity for the material. In some embodiments, the electrodes 240, 250 may have power factors of about or greater than 0.01 W/m-K². A set of exemplary high power factor materials for use as electrodes 240, 250 is shown in Table 2.

TABLE 2

| P-Type TE | N-type TE | Operating |
|---|---|---|
| Material | Material | Temperature (° C.) |
| B-doped Si | P-doped Si | 0-1000 |
| CoSb₃ | Yb-doped CoSb₃ | 200-650 |
| | Mg₂Si | 400-700 |
| CePd₃ | YbAl₃ | 0-1000 |

In some embodiments, the thermoelectric layers 200 may include one or more thin-film layers. A part of the thermoelectric layers 290 may be, optionally, formed into a hemisphere 205 around part: of the diffusion barrier 220. This hemisphere 205 may increase heat spreading along the surface of the layers 200. Each of the layers 200a, 200b, 200c, 200d may have similar or different thicknesses and may operate in different temperature ranges. For example, the innermost thermoelectric layer 100d, closest to the illusion barrier 220, may have a temperature range of 200 degrees C. to 50 degrees C., where the hot side is at 200 degrees C. and cold side is at 50 degrees C. The outermost layer 100a, which is closest to the metal substrate 120, may have a temperature range of about 650 degrees C. to about 400 degrees C., with the hot side of the outermost layer being at about 650 degrees C. and the cold side of the outermost layer 100a being at about 400 degrees C. The plurality of thermoelectric layers 200 may comprise two or more layers, and the temperature ranges and thicknesses of the thermoelectric layers 200 may be varied, as would be understood by a person of ordinary skill in the art with the benefit of the present disclosure.

The number of thermoelectric layers and the number of phonon barriers can vary with the desired power generation level per thermoelement 110. The thermoelectric layer thickness may depend on the electron-phonon thermolization length and the nature of material grain growth. Exemplary thermoelectric layer thicknesses may be but are not limited to is range of 0-500 nanometers. In some embodiments, one or more of the thermoelectric layers 200 may have sub-layers. Table 3 shows characteristics of an exemplary set of thermoelectric layers with thicknesses for a three-layer embodiment of a thermoelement.

TABLE 3

| Segment | | Temperature | Nominal |
|---|---|---|---|
| Layer | Stoichiometry | Range (Deg. C.) | Thickness (nm) |
| 1 | Bi_{0.5}Sb_{1.5}Te₃/Bi₂Te₃ | 30-200 | 2500 |
| 2 | Zn₄Sb₃/AgPb₁₈SbTe₂₀ | 200-400 | 100 |
| 3 | CeFe_{3.5}Co_{0.5}Sb₁₂/ | 400-650 | 500 |
| | Ba_{0.08}Yb_{0.09}Co₄Sb₁₂ | | |

Some exemplary materials that may be used as the thermoelectric layers 200a, 200b, 200c, 200d include intrinsically disordered tellurides such as LAST (AgPb₁₈SbTe₂₀), and antimonides, such as β-Zn₄Sb₃ have shown reduced mean free paths for phonons and ZT>18. At higher temperatures (400-700 degrees C.), the filled skutterudites such as Ba_{0.08}Yb_{0.09}Co₄Sb₁₂, CeFe_{3.5}Co_{0.5}Sb₁₂) and clathrates (such as Ba₈Ga₁₆Ge₃₀) with rattling weakly-bound atoms, polar zintl phases (such as Yb₁₄MnSb₁₁), semiconducting oxides (such as NaCo₂O₄), and metal oxides (such as SrTiO₃) with complex structures and increased optical phonon modes, have varied degree of performance with ZTs>1. Rattling refers to a property of atoms in a material where the atoms are weakly bound within a lattice cage. Rattling atoms may have modes, such as low frequency modes, where they are more efficient at scattering acoustic phonons, resulting in lower thermal conductivity.

In some embodiments, the thermoelectric layers 200a, 200b, 200c, 200d may be deposited using a combination of Physical Vapor Deposition (PVD) sputtering and Atomic Layer Deposition (ALD)/Chemical Vapor Deposition (CVD) techniques. The phonon blocking layers may be deposited using ALL) or CVD techniques.

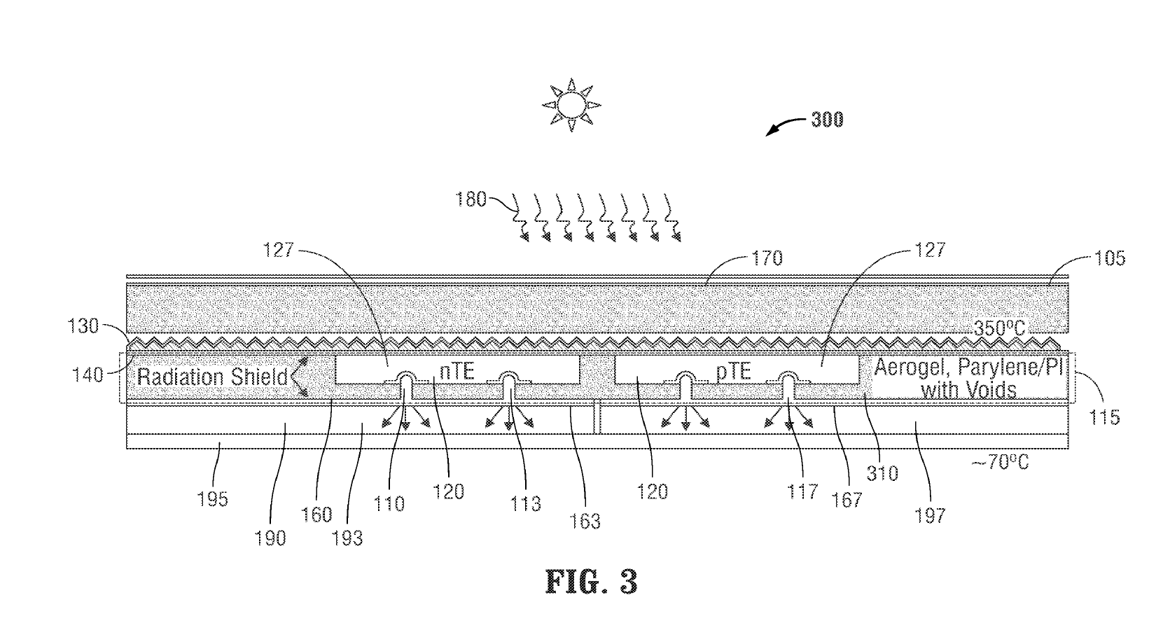

FIG. 3 shows a diagram of another exemplary solar TEG apparatus 300 according to one embodiment of the present disclosure. A thermal insulator 310 may be disposed between the radiation shields 140, 160 to reduce thermal conduction outside the conduction path through the metal substrates 120 and thermoelements 110. The thermal insulator 310 may be comprised of a low thermal conductivity material, such as aerogels and high temperature polyimides with voids.

Aerogels are synthetic porous materials derived from alcogels, where the liquid component of the gel is replaced by air through supercritical drying. Silica aerogels (prepared b hydrolysis and condensation of methanol diluted TMOS) are the most common aerogels that consist of nanostructured Silicon dioxide network with a porosity of up to 99%. In terms of space occupied, the interconnected backbone can be as little as 0.01% of the structure, with the remainder being comprised of air. Due to its extraordinary small pore sizes (varying between 50 and 100 nm) and high porosity, aerogels achieve their structural properties (ultra low density 3 kgm-3, high compression strength up to about 3 bar, but very low tensile stress). Aerogels may also demonstrate thermal (thermal conductivity ˜0.0129 W m-₁ K-₁ is much lower than that of still air ˜0.024 W m-₁K-₁) and optical properties (˜95% transparency in the visible region). Because of the ultra-low thermal conductivity and high transmittance of daylight, aerogels are considered as highly suitable thermal insulation materials for windows and solar collectors. Pure silica aerogels, though suitable for low temperature insulating applications, are transparent to radiation wavelengths between 3 to 8 micrometers, where radiative heat transfer may be significant.

In some embodiments, mineral powders, such as titanium dioxide, silicon carbide, and carbon black may be incorporated into the silicon dioxide backbone of the silica aerogel improve resistance to structural deformation and cracking due to high temperatures. The use of silicon dioxide as the backbone material is exemplary and illustrative only, as other backbone materials may be used, such as ZrSiO₄. In some embodiments, a small amount (about 20% by weight or less) of carbon powder may be added to the aerogel backbone to increase elasticity without decreasing or only nominally decreasing hardness. The mean extinction coefficient, which characterizes radiative attenuation, of silica aerogel with 20 wt % carbon is about 100 m²/kg. By comparison, pure silica aerogel has a mean extinction coefficient of about 20 m²/kg; silica aerogel with 20 wt % of silicon carbide ha a mean extinction coeffient of about 52.5 m²/kg; and silica aerogel with 40 wt % of ZrSiO₄ has a mean extinction coefficient of about 21.4 m²/kg. In some embodiments, multiple aerogel layers of different types may be combined to capitalize on their properties (pure silica aerogel is highly optically transparent, silica aerogel with 20 wt % carbon has a high mean extinction coefficient, silica aerogel with 20 wt % silicon carbide has high thermal stability).

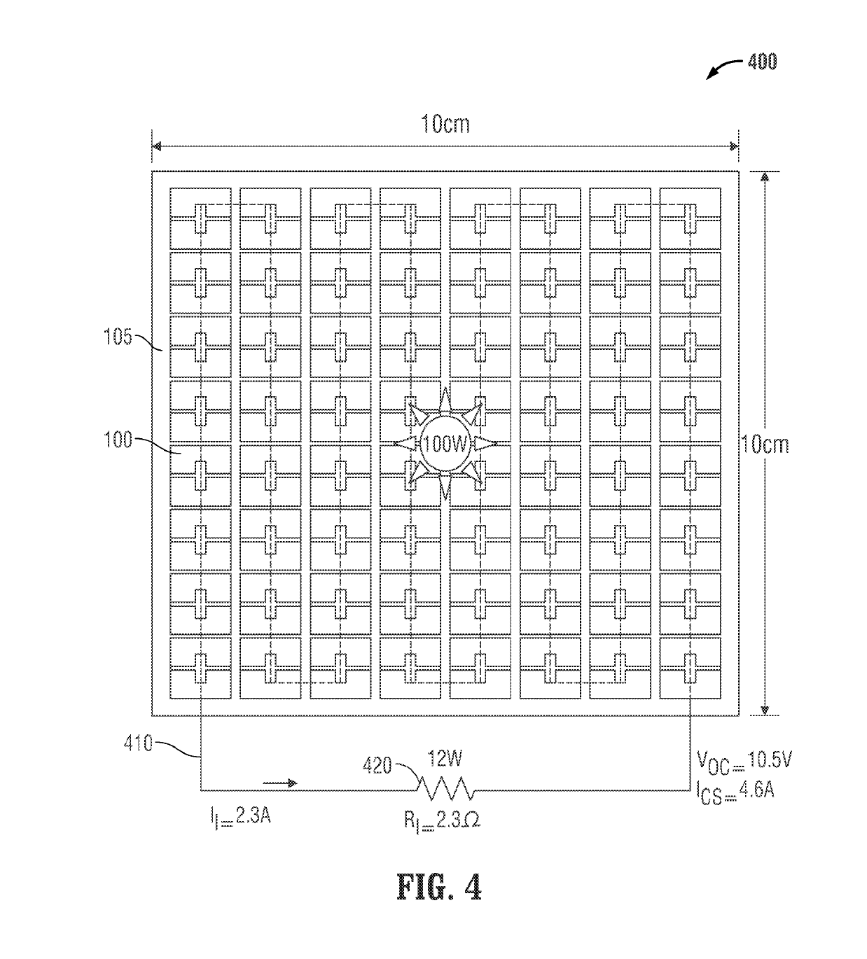

FIG. 4 shows an exemplary solar TEG module 400 according to one embodiment of the present disclosure. The module 400 may include an array of solar TEG apparatuses 100, and shown in FIG. 4 as an 8×8 array. When configured as module 400, some elements may be common for two or more of the apparatuses 100. For example, the module 400 may include 64 thermocouples 115, but may only have a single panel 105, or a series of panels 105 that include more than one thermocouple 115. Common elements may include the panel 105, the selective wavelength absorber 130, the radiation shield 140, and the foil 195. The module 400 may be arranged with a circuit 410 whereby all 64 apparatuses 100 are in series. While shown with 64 apparatuses 100 in series, this is exemplary and illustrative only, as there can be any number of apparatuses 100 or thermocouples 115 in the module 400 and they may be arrayed in series, parallel, or a hybrid of series and parallell. The module 400 may be connected to a load 410. The load 410 may include one or more of an energy storage device and an electrically powered device. Also shown are exemplary currents and voltages corresponding to thermoelectric materials with figure of merit ZTₘ=1 when the module 400 is exposed to 100W of electromagnetic, radiation over a 100 cm² area. (equivalent to 10 times the insolation rate).

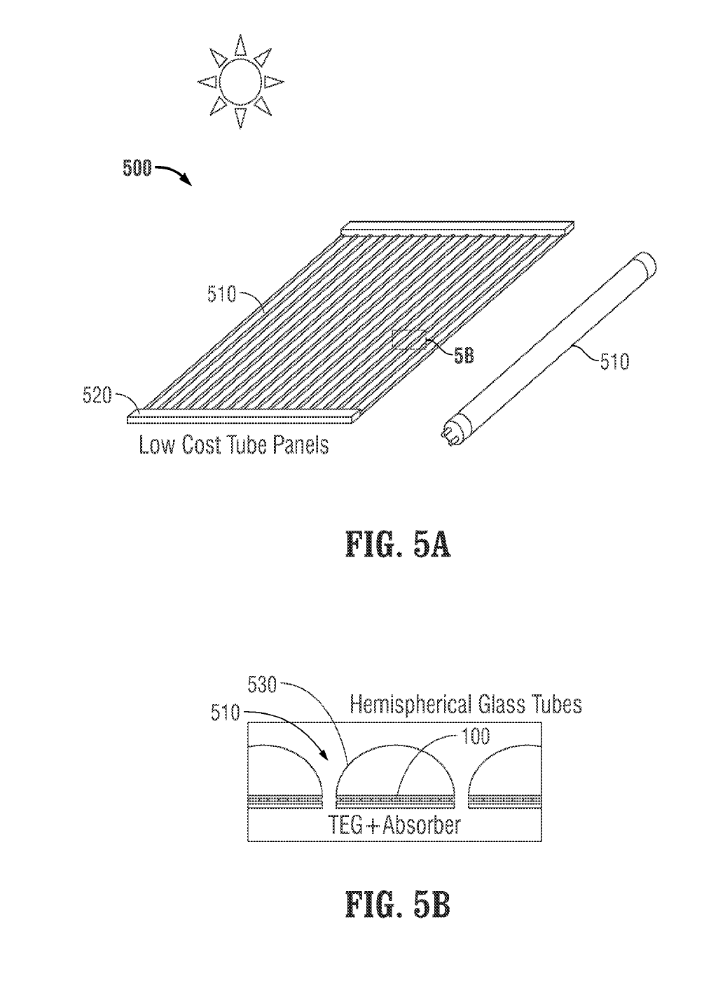

FIG. 5A shows the design of a solar TEG panel 500 according to one embodiment of the present disclosure. The solar TEG panel 500 may include a series of thermoelectric tubes 510. The tubes 510 may be mounted on an electric bus 520 configured to receive over generated by the tubes 510 or to make a series connection between tubes 510. Each tube may include two or more thermocouples 115 with a selective wavelength absorber 130. The selective wavelength absorber 115 may be associated with one or more thermocouples 115.

FIG. 58 shows a cross-sectional view of tube 510. Each tube 510 may include a hemispherical enclosure 530 that may also be tubular. The hemispherical enclosure 530 may be transparent to visible electromagnetic waves and may also be configured to maintain a vacuum or low pressure atmosphere around the thermocouple 115.

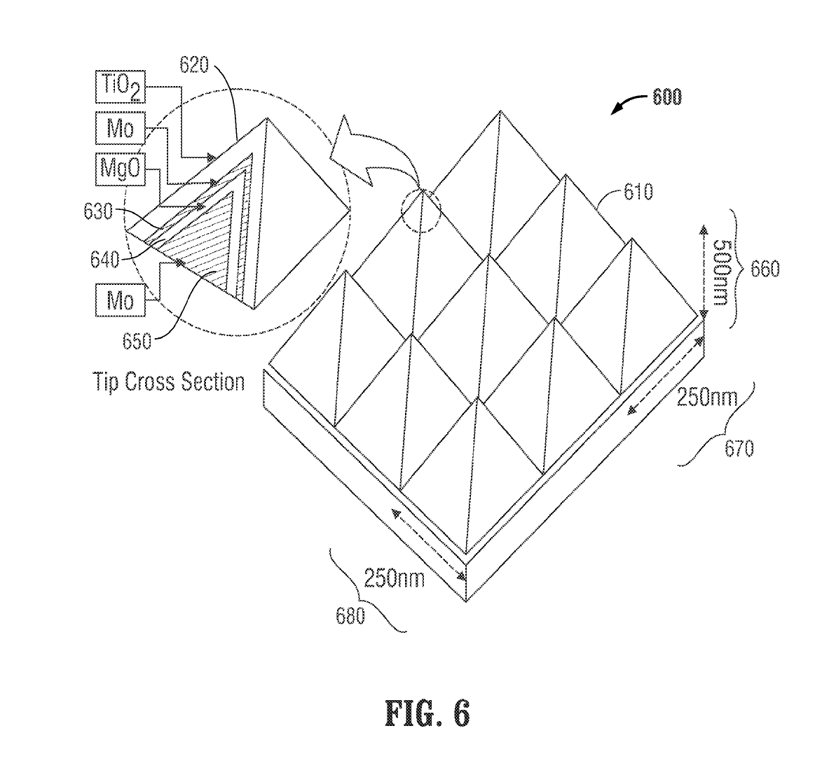

FIG. 6 shows a, schematic of an exemplary selective section 600 of the wavelength absorber 130 according to one embodiment of the present disclosure. The selective wavelength absorber 130 may be configured to capture incident photons over a wide range incident angles. In some embodiments, the selective wavelength absorber 130 may be configured to capture incident photons over an angular range of 0 to 60 degrees. The selective wavelength absorber 130 may include absorbers 610, which may be pyramidal in Shape and grouped into sections 600. The use of pyramidal shape is exemplary and illustrative only as other shapes may be used including flat embodiments. Generally, non-flat surfaces have greater surface areas resulting in less of the incoming electromagnetic energy being reflected back to free space. The pyramids may have different heights and/or height/base ratios to increase absorptivity. Each absorber 610 may include multiple layers 620, 630, 640, 650. The absorber 610 may incorporate surface texturing (improved capturing of photons and enhanced spectral selectivity) and layers (interference enhancement of absorptivity). The efficiency of the absorber 610 may be increased by decreasing an impedance mismatch between free space and the absorber surface, Generally, reflection of the incoming electromagnetic energy is a function of the impedances of free space and the materials that make up the selective wavelength absorber 139. The lattice array of pyramidal structures may reduce impedance mismatch and increase absorptivity of the surface of the selective wavelength absorber 130. Absorption characteristics of the absorbers 610 may be adjusted by timing the height 660 of the pyramidal structure Herein the exemplary height 660 is 500 nanometers. The greater the height relative to the base dimensions, the more gradual the change from free space to the layers. As shown, base dimensions are as length 670 of 250 nanometers and a width 680 of 250 nanometers. Other ratios are also possible, such as 250 nanometers per side in the base with a height of 750 nanometers.

These layers may include absorption layers and dielectric layers. The dielectric layers may act as optical spacers. A first dielectric layer 620 of the absorber 610 ma disposed on a first absorber layer 630. The first absorber layer 630 may be disposed on a second dielectric layer 640, which may be disposed on a second absorber layer 650. These layers 620, 639, 640, 650 of absorbers and dielectrics may alternate for as many layers as is desired. Typical embodiments may include 4-10 layers. Each of the layers 620 630, 640, 650 may vary in thickness, usually between 5 and 100 nanometers. The number and thickness of the layers 620, 630, 640, 650 may provide flexibility in maximizing after of the absorber 610 for a desired operation temperature, where α is the absorptance and is the emittance of the absorber 610. The interference of photons between these layers 620, 630, 640, 650 may result in enhanced absorption in the desired spectral range.

The dielectric layers 620, 640 may be made of a suitable material with a high dielectric cons ant, a high refractive index, and good thermal stability against long term oxidation. The first dielectric layer 620 may be made of titanium dioxide, and the second dielectric layer 640 may be made of magnesium oxide. The use of titanium dioxide and magnesium dioxide as the dielectric layers, and their respective order, are exemplary and illustrative only, as other suitable materials, such as i) titanium aluminum nitride, ii) titanium aluminum ox nitride, iii) TiNOX, iv) metal-dielectric composites (i.e. nanometer-sized metal particles embedded in a ceramic host matrix, including, Pt—Al₂O₃, Ni—Al₂O₃ can be used as selective absorber coatings), and v) other transition metal oxides, may be used its understood by a person of ordinary skill in the art with the benefit of the present disclosure.

The absorber layers 630, 650 may be comprised of a material selected for thermal stability at about 700 degrees K, good infra-red wavelength reflectance and visible wavelength absorbance. In some embodiments, the absorber layers 630, 650 may be made of molybdenum. In a multilayer metal-dielectric stack as shown in FIG. 6, where metal layers act as good absorbers and the dielectric layers as optical spacers, interference of photons between these layers may result in enhanced absorption in the desired spectral range. Molybdenum may be used as the absorber layers 630, 650 for its thermal stability, high reflectance in the infrared region and good solar absorptance. Transition metal oxide coatings like HfO₂ (Tₘ=3031K), MgO (Tₘ=3125K) may be suitable for the dielectric layers 620, 640 due to their excellent optical properties (high dielectric constant, high refractive index) and good thermal stability. The use of molybdenum is exemplary and illustrative only, as other suitable materials may be used as understood by a person of ordinary skill in the art with the benefit of the present disclosure.

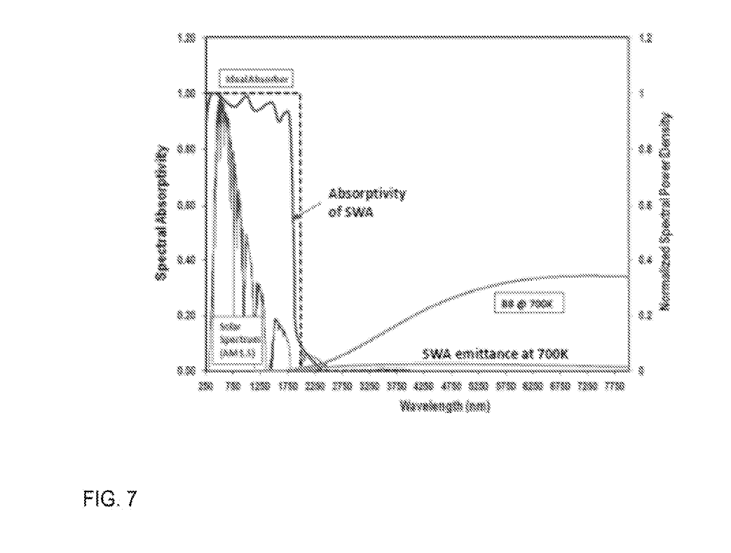

FIG. 7 shows a graph of the optical characteristics of an exemplary selective wavelength absorber 130 operating at about 700K according to one embodiment of the present disclosure. The selective wavelength absorber 130 may have a high absorptance (α=1) for wavelengths ≦(λ_{c}=2 μm) at Tₒₚₜ=700K and zero emittance (ε=0) for larger wavelengths where the spectral density of a black body at similar temperature is significant. The graph shows the high spectral absorptivity of the selective wavelength absorber 130 in the visible electromagnetic spectrum. As can be seen in FIG. 7, the selective, wavelength absorber 130 has high absorptance (α) in the entire solar spectral range (0.3-2.5 micrometers) and low emittance (ε) in the infra-red region (≧2.5 micrometers). Thus, fergy for all λ<λ_{C} (characteristic wavelength) are absorbed and thermal emission (ε=0) for all λ>λ_{C}, minimizing losses through infra-red emission.

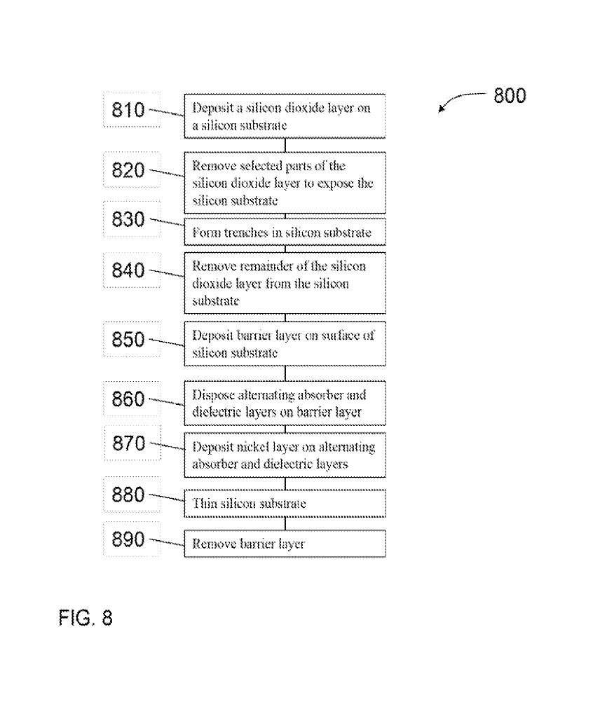

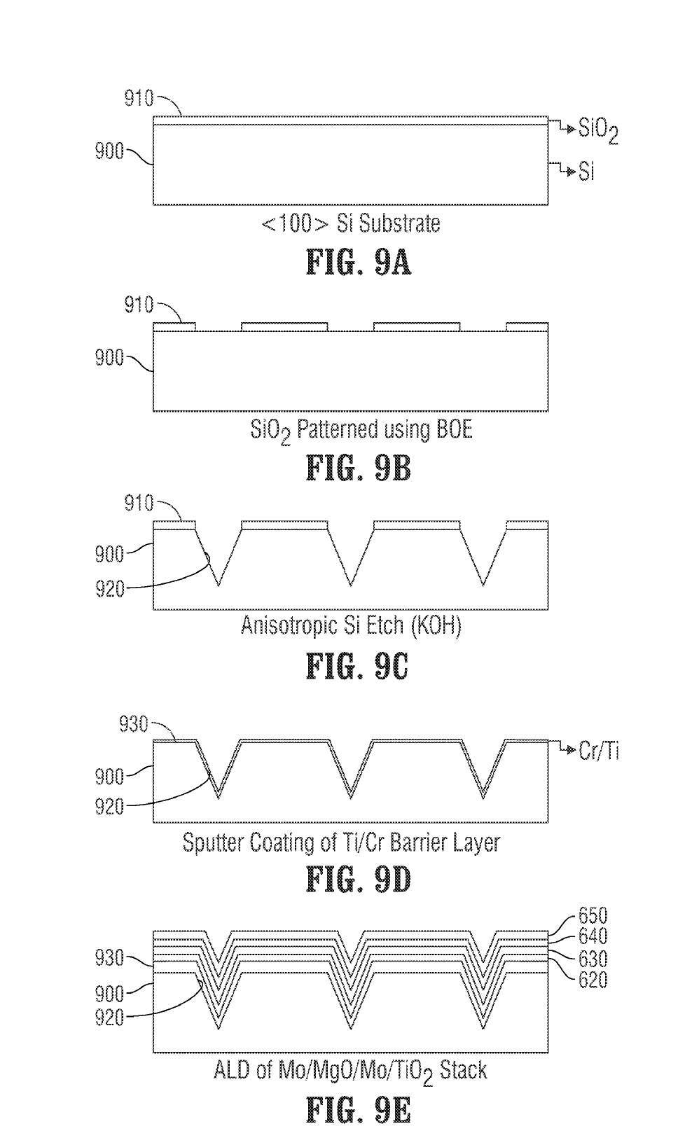

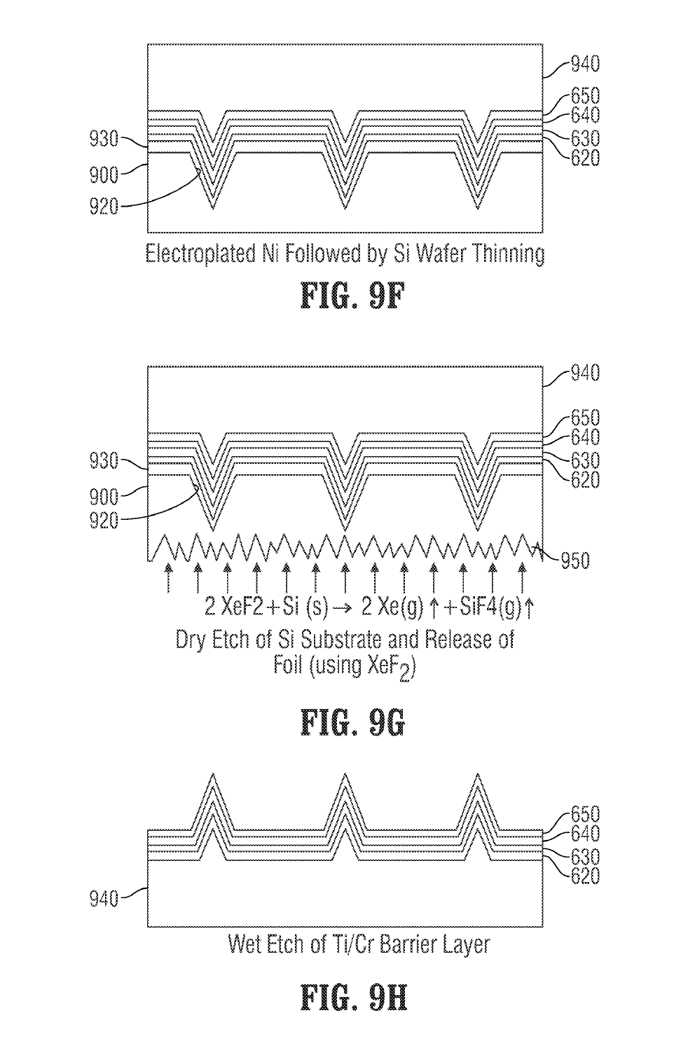

FIG. 8 shows an exemplary method 800 for manufacturing the selective, wavelength absorber 130 according to one embodiment of the present disclosure. In step 810, a silicon substrate 900 (FIG. 9A) is obtained with a silicon dioxide layer 910 (FIG. 9A) on one surface. In step 820, the silicon dioxide layer 910 may be partially removed, to reveal exposed sections of the silicon, substrate 900. The partial removal may be performed using I-line lithography. In step 830, trenches 920 (FIG. 9C) may be formed in the silicon substrate 900. The trenches 920 may be formed using anisotropic etching. The anisotropic etching may include application of potassium hydroxide to the silicon substrate 900. In some embodiments, the trenches 920 may be further deepened with additional etching using a cesium hydroxide or reactive ion etch. In step 840, the remainder of the silicon dioxide layer 910 may be removed from the silicon substrate 900. The removal of the silicon dioxide layer 910 may include using buffered oxide etching. In step 850, a barrier layer 930 (FIG. 9D) may be added to the trench 920. The barrier layer 930 may include titanium and/or chromium. The harrier layer 930 may be added using a splitter coating technique. In step 860, the alternating absorber layers 630, 650 and dielectric layers 620, 640 ma be disposed on top of the barrier layer 930. The alternating layers may be applied using an ALD process. In step 870, a nickel layer 940 (FIG. 9F) may be deposited on the alternating layers 620, 630, 640, 650. The nickel layer 940 may be deposited through electroplating. In step 880, the silicon substrate 900 may be dry etched with xenon fluoride to form a thinned silicon substrate 950 (FIG. 9G). In some embodiments, step 880 may, in the alternative, include thermal exfoliation methods to conserve the silicon substrate 900 for subsequent use and lower cost of the processing. In step 890, the barrier layer 930 may be removed to reveal the selective wavelength absorber 130. The barrier layer 930 may be removed using a Wet etching process, the steps of removing and depositing layers 820-890 are not limited to the etching and deposition techniques described in detail above, but include techniques known to persons of ordinary skill in the art with the benefit of the present disclosure.

FIGS. 9A-9H shows a series of stages of manufacture for selective wavelength absorber 130 according, to one embodiment of the present disclosure. FIG. 9A shows a silicon substrate 900 with a layer of silicon dioxide 910. FIG. 9B shows the silicon dioxide after patterning. FIG. 9C shows the silicon substrate 900 with trenches 920. The trenches 920 may be pyramidal-shaped with walls with angles at 54.7 degrees. En some embodiments, deeper trenches may be obtained by using a cesium hydroxide or reactive ion etching after the potassium hydroxide etching. FIG. 9D shows a chromium/titanium barrier layer 930 deposited on the silicon substrate 900. The remainder of the silicon dioxide has been removed though buffered oxide etching. In some embodiments, the buffered oxide etching uses a solution of 6 parts of 40% NH₄F and 1 part of 49% HF. FIG. 9E shows layers 620, 630, 640, 650 deposited on the barrier layer 930. FIG. 9F shows electroplated nickel 940 deposited on the layer 650. FIG. 9G shows a thinning 950 of the silicon substrate 900. FIG. 911 shows the selective wavelength absorber 130 once the barrier layer 930 has been removed.

While the disclosure has been described with reference to exemplary embodiments, it will be understood that various changes may be made and equivalents may be substituted for elements thereof without departing from the scope of the disclosure. In addition, many modifications will be appreciated to adapt a particular instrument, situation or material to the teachings of the disclosure without departing from the essential scope thereof. Therefore, it is intended that the disclosure not be limited to the particular embodiment disclosed as the best mode contemplated for carrying, out this disclosure, but that the disclosure will include all embodiments falling within the scope of the appended claims.

We claim:

1. An apparatus for generating electric power from electromagnetic radiation, the apparatus comprising:
a thermoelectric generator, the thermoelectric generator having a hot side and a cold side; and
an electromagnetic radiation absorber in thermal communication with the of side and configured to convert electromagnetic energy into heat energy.

2. The apparatus of claim 1, wherein the electromagnetic radiation absorber has high absorbance and low emittance over an operating temperature range of the thermoelectric generator.

3. The apparatus of claim 1, wherein the electromagnetic radiation absorber is configured to absorb electromagnetic radiation in the visible spectrum.

4. The apparatus of claim 1, wherein the electromagnetic radiation absorber is configured to have low emittance of electromagnetic radiation in the infra-red spectrum.

5. The apparatus of claim 1, wherein the electromagnetic radiation absorber comprises a plurality of absorber layers; and
a plurality of dielectric layers, wherein the absorber layers and the dielectric layers alternate.

6. The apparatus of claim 5, wherein the plurality of absorber layers comprises a titanium dioxide layer and a magnesium oxide layer.

7. The apparatus of claim 5, wherein the plurality of dielectric layers comprises molybdenum.

8. The apparatus of claim 5 wherein the plurality of absorber layers and the plurality of dielectric layers are configured in a pyramidal shape.

9. The apparatus of claim 8, wherein the pyramidal shape is dimensioned based on a selected range of wavelengths of electromagnetic radiation.

10. The apparatus of claim 1, further comprising:
a housing, wherein the thermoelectric, generator and the electromagnetic radiation absorber are disposed in the housing, and wherein the housing is transparent to a selected range of electromagnetic radiation on a side of the housing that is between an electromagnetic radiation source and the electromagnetic radiation absorber.

11. The apparatus of claim 10, wherein the selected range of electromagnetic radiation comprised the visible spectrum.

12. The apparatus of claim 10, wherein the housing is configured to maintain a vacuum.

13. The apparatus of claim 10, wherein the housing has an interior, and the interior is filled with an aerogel that is substantially transparent to visible light.

14. The apparatus of claim 1, wherein the thermoelectric generator comprises at least one thermocouple.

15. The apparatus of claim 14, wherein the at least one thermocouple comprises:
a first radiation shield in thermal communication with the electromagnetic radiation absorber;
a first metal substrate layer in thermal and electrical communication with the first radiation shield;
at least one n-type thermoelement in thermal communication with the first metal substrate;
a first substrate layer in thermal communication with the at least one n-type thermoelement;
a second metal substrate layer in thermal and electrical communication with the first radiation shield;
at least one p-type thermoelement in thermal communication with the second metal substrate;
a second substrate layer in thermal communication with the at least one p-type thermoelement; and
a foil layer in thermal communication with the first substrate layer and the second substrate layer.

16. The apparatus of claim 15, further comprising:
an n-side second radiation shield disposed between the at least one n-type thermoelement and the first substrate layer; and
a p-side second radiation shield disposed between the at least one p-type thermoelement and the second substrate layer.

17. The apparatus of claim 15, wherein the foil layer is an anodized metal.

18. The apparatus of claim 15, further comprising:
a housing, wherein the thermoelectric generator and the electromagnetic radiation absorber are disposed in the housing, and wherein the foil layer has a thermal expansion coefficient that is substantially equal to a thermal expansion coefficient of the housing.

19. The apparatus of claim 15, wherein the foil layer is configured to provide structural support to the thermocouple.

20. The apparatus of claim 15, wherein the at least one n-type thermoelement comprises:
a first constricted contact,
a first diffusion barrier disposed on the first constricted contact;
a first lower electrical contact disposed on the first diffusion barrier;
a plurality of n-type thin-film thermoelectric layers in thermal communication with the first metal substrate; and
a first upper electrical contact disposed between the plurality of n-type thin-film thermoelectric layers and the first metal substrate.

21. The apparatus of claim 20, wherein the electrical contacts are high power factor electrodes.

22. The apparatus of claim 20, wherein the n-type thermoelectric layers comprise one or more of: Bi₂Te_{2.8}Se_{0.2}, PbTe, AgPb_{1.8}SbTe₂₀, PbTe/SrTe—Na, Ba_{0.08}Yb_{0.09}Co₄Sb₁₂, Mg₂Si_{0.4}Sn_{0.6}, TiNiSn, SrTiO₃, P-doped Si, P-doped Si_{0.8}Ge_{0.2}, and La₃Te₄.

23. The apparatus of claim 15, wherein the at least one p-type thermoelement comprises:
a second constricted contact:
a second diffusion barrier disposed on the second constricted contact
a second lower electrical contact disposed on the second diffusion barrier;
a plurality of p-type thin-film thermoelectric layers in thermal communication with the second metal substrate; and
a second upper electrical contact disposed between the plurality of p-type thin-film thermoelectric layers and the second metal substrate.

24. The apparatus of claim 23, wherein the electrical contacts are high power factor electrodes.

25. The apparatus of claim 23, wherein the p-type thermoelectric layers comprise one or more of Bi_{0.5}Sb_{1.5}Te₃, Zn₄Sb₃, CeFe_{3.5}Co_{0.5}Sb_{1.2}, Yb₁₄MnSb₁₁, MnSi_{1.73}, NaCo2O4, B-doped Si, and B-doped Si_{0.8}.Ge_{0.2}.

26. The apparatus of: claim 14, wherein the at least one thermocouple comprises
a first radiation shield in thermal communication with the electromagnetic radiation absorber,
at least one n-type thermoelement in thermal communication and electrical communication with the first radiation shield
a first substrate layer in thermal communication with the at least one n-type thermoelement;
at least one p-type thermoelecric in thermal communication and electrical communication with the first radiation shield;
a second substrate layer in thermal communication with the at least one p-type thermoelement;
a foil layer in thermal communication with the first substrate layer and the second substrate layer;

27. The apparatus of claim 26, further comprising:
an n-side second radiation shield disposed between the at least one n-type thermoelement and the first substrate layer:, and
p-side second radiation shield disposed between the at least one p-type thermoelement and the second substrate layer.

28. The apparatus of claim 26 wherein the toil layer is an anodized metal.

29. The apparatus of claim 26, further comprising:
a housing, wherein the thermoelectric generator and the electromagnetic radiation absorber are disposed in the housing, and wherein the foil layer has a thermal expansion coefficient that is substantially equal to a thermal expansion coefficient of the housing.

30. The apparatus of claim 26, wherein the foil layer is configured to provide structural support to the thermocouple.

31. The apparatus of claim 26, wherein the at least one n-type thermoelement comprises:
a first constricted contact;
a first diffusion barrier disposed on the first constricted contact
a first lower electrical contact disposed on the first diffusion barrier;
a plurality of n-type thin-film thermoelectric layers in thermal communication with the first metal substrate; and
a first upper electrical contact disposed between the plurality of n-type thin-film thermoelectric layers and the first metal substrate.

32. The apparatus of claim 31, wherein the electrical contacts are high power factor electrodes.

33. The apparatus of claim 31, wherein the n-type thermoelectric, layers comprise one or more of:
Bi₂Te_{2.8}Se_{0.2}, PbTe, AgPb₁₈SbTe₂₀, PbTe/SrTe—Na, Ba_{0/08}Yb_{0.09}Co₄Sb₁₂, Mg₂Si_{0.4}Sn_{0.6}, TiNiSn, SrTiO₃, P-doped Si, P-doped Si_{0.8},Ge_{0.2}, and La₃Te₄.

34. The apparatus of claim 26 wherein the at least one p-type thermoelement comprises:
a second constricted contact;
a second diffusion barrier disposed on the second constricted contact
a second lower electrical contact disposed on the second diffusion barrier;
a plurality of p-type thin-film thermoelectric layers in thermal communication with the second metal substrate; and
a second upper electrical contact disposed bet wee the plurality of p-type thin-film thermoelectric layers and the second metal substrate.

35. The apparatus of claim 34, valerein the electrical contacts are high power factor electrodes.

36. The apparatus of claim 34, wherein the p-type thermoelectric layers comprise one or more of: Bi_{0.5}Sb_{1.5}Te₃, Zn₄Sb₃, CeFe_{3.5}Co_{0.5}Sb₁₂, Yb₁₄MnSb₁₁, MnSi_{1.73}, NaCo2O4, B-doped Si, and B-doped Si_{0.8}Ge_{0.2}.

37. The apparatus of claim 14, wherein the at least one thermocouple comprise:
a first metal substrate layer in thermal and electrical communication with the electromagnetic radiation absorber;
at least one n-type thermoelement in thermal communication with the first metal substrate;
a first substrate layer m thermal communication with the at least one n-type thermocouple;
a second metal substrate layer in thermal and electrical communication with the electromagnetic radiation absorber;
at least one p-type thermoelement in thermal communication with the second metal substrate;
a second substrate layer in thermal communication with the at least one p-type thermoelement; and
a foil layer in thermal communication with the first substrate layer and the second substrate layer.

38. The apparatus of claim 37, further comprising:
an n-side second radiation shield disposed between the at least one n-type thermoelement and the first substrate layer; and
a p-side second radiation shield disposed between the at least one p-type thermoelement and the second substrate layer.

39. The apparatus of claim 37, wherein the foil layer is an anodized metal.

40. The apparatus of claim 37, further comprising:
a housing, wherein the thermoelectric generator and the electromagnetic radiation absorber are disposed in the housing, and wherein the foil layer has a thermal expansion coefficient that is substantially equal to a thermal expansion coefficient of the housing,

41. The apparatus of claim 37, wherein the foil layer is configured to provide structural support to the thermocouple.

42. The apparatus of claim 37, wherein the at least one n-type thermoelement comprises:
a first constricted contact;
a first diffusion barrier disposed on the first constricted contact
first lower electrical contact disposed on the first diffusion barrier;
a plurality of n-type thinfilm thermoelectric layers in thermal communication with the first metal substrate; and
a first upper electrical contact disposed between the plurality of n-type thin-film thermoelectric layers and the first metal substrate.

43. The apparatus of claim 42, wherein the electrical contacts are high power factor electrodes.

44. The apparatus of claim 42, wherein the n-type thermoelectric layers comprise, one or more of Bi₂Te_{2.8Se}_{0.2}, PbTe AgPb₁₈SbTe₂₀, PbTe/SrTe—Na. Ba_{0.08}Yb_{0.09}Co₄Sb₁₂, Mg₂Si_{0.4}Sn_{0.6}, TiNiSn, SrTiO₃, P-doped Si, P-doped Si_{0.8}Ge_{0.2}, and La₃Te₄.

45. The apparatus of claim 37, wherein the at least one p-type thermoelement comprises:
a second constricted contact;
a second diffusion harrier disposed on the second constricted contact
a second lower electrical contact disposed on the second diffusion barrier;
a plurality of p-type thin-film thermoelectric layers in thermal communication with the second metal substrate and
a second upper electrical contact disposed between the plurality of p-type thin-film thermoelectric layers and the second metal substrate,

46. The apparatus of claim 45, wherein the electrical contacts are high power factor electrodes.

47. The apparatus of claim 45, wherein the p-type thermoelectric layers comprise one or more of: Bi_{0.5}Sb1.5Te₃, Zn₄Sb₃, CeFe3.5Co0.5Sb₁₂, Yb₁₄MnSb₁₁, MnSi_{1.73}, NaCo2O4, B-doped Si, and B-doped Si_{0.8}Ge_{0.2}.

48. A method of converting electromagnetic radiation to heat energy, the method comprising the steps of:
receiving the electromagnetic radiation with an apparatus, the apparatus comprising:
a thermoelectric generator, the thermoelectric generator having a hot side and a cold side; and
an electromagnetic radiation absorber in thermal communication with the hot side and configured to convert electromagnetic energy into heat energy.

49. The method of claim 48, further comprising the step of:
concentrating the electromagnetic radiation on the electromagnetic radiation absorber.

50. The method of claim 48, further comprising the step of:
redirecting the electromagnetic, radiation from an electromagnetic source on to the electromagnetic radiation absorber,

51. The method of claim 48, wherein the electromagnetic, radiation comprises visible light,

52. A method of manufacturing an electromagnetic radiation driven thermoelectricenerator the method comprising the steps of:
forming an electromagnetic radiation absorber; and
disposing the electromagnetic radiation absorber in thermal communication with a hot side of a thermoelectric generator.

53. The method of claim 52, wherein the forming step comprises:
depositing a silicon dioxide layer on a silicon substrate;
removing a part of the silicon dioxide layer to expose the silicon substrate;
forming trenches in the silicon substrate;
removing a remainder of the silicon dioxide layer from the silicon substrate;
depositing a barrier layer on the silicon substrate;
depositing alternating layers of electromagnetic absorber material and dielectric, material on the barrier layer;
depositing a nickel layer on the alternating layers;
thinning the silicon substrate; and
removing the barrier layer from the alternating layers.

54. The method of claim 53, wherein the silicon dioxide removal is performed by anisotropic etching.

55. The method of claim 53, wherein the depositing the barrier layer is performed by sputter coating.

56. The method of claim 53, wherein the barrier layer comprises at east one of titanium and chromium.

57. The method of claim 53, wherein the alternating layers are deposited using atomic layer deposition.

58. The method of claim 53, wherein the nickel layer is deposited using electroplating.

59. The method of claim 53, wherein the step of thinning the silicon substrate is performed using at least one of: dry etching, and thermal exfoliation.

60. The method of claim 53, wherein the step of removing the barrier layer is performed using wet etching.
